(19) United States
(12) Patent Application Publication
(10) Pub. No.: US 2026/0293022 A1
(43) Pub. Date: Sep. 24, 2026

(54) LOCKING DEVICE AND TERMINAL DEVICE

(71) Applicant: Fulian Precision Electronics (Tianjin) Co., LTD., Tianjin (CN)

(72) Inventors: HSIAO-HSUAN CHANG, New Taipei (TW); WEN-LING CHIANG, New Taipei (TW)

(21) Appl. No.: 19/229,004

(22) Filed: Jun. 5, 2025

(30) Foreign Application Priority Data
Mar. 21, 2025 (CN) 202510342995.8

(51) Int. Cl. H05K 7/14

(52) U.S. Cl. CPC H05K 7/1407; H05K 7/1405; H05K 7/1409

(57) ABSTRACT

A locking device can lock with a component having a slot. The locking device includes a base, a fixing member, a movable member, a driving member, and an elastic member. The base defines a guide groove extending along a first direction. The guide groove can drive the component to slide in the guide groove. The movable member can move and rotate around the first direction. The movable member is engageable with the slot by extending into the guide groove along a second direction. The driving member rotates and drives the movable member to move along the first direction. The elastic member is deformable along the first direction and torsional deformable around the first direction, when the elastic member is compressive deformed and torsional deformed the movable member is driven to return to an original position. The present disclosure further provides a terminal device.

The subject matter herein generally relates to locking technologies, and more particularly, to a locking device and a terminal device.

### BACKGROUND

Circuit boards need to be detachably locked in servers. The circuit boards typically need to be manually pushed into or pulled out of the servers during use, which is difficult for users to operate due to the limited space in the servers. Therefore, there is a room for improvement in the art.

### SUMMARY

The present disclosure provides a locking device that can automatically reset and occupies minimal space, as well as a terminal device incorporating the same.

In one embodiment of the present disclosure, a locking device can lock with a component having a slot. The locking device includes a base, a fixing member, a movable member, a driving member, and an elastic member. The base defines a guide groove. The guide groove extends along a first direction. The guide groove is slidably connected to the component, thereby driving the component to slide in the guide groove along the first direction. The fixing member is fixed to the base. The movable member can move along the first direction and rotate around the first direction. The movable member is engageable with the slot by extending into the guide groove along a second direction. The driving member is rotatably connected to the base. The driving member can rotate around the second direction to drive the movable member to move along the first direction. The elastic member is connected to the movable member and the fixing member, the elastic member is deformable along the first direction and torsional deformable around the first direction, when the elastic member is compressive deformed and torsional deformed the movable member is driven to return to an original position.

The base further includes an inclined surface intersecting with each of the first direction and the second direction. The inclined surface can block the movable member to cause the movable member to rotate around the first direction, thereby driving the movable member to be disengaged from the slot.

The movable member includes a first rod portion, a connecting portion, and a blocking portion. The connecting portion is connected to the first rod portion and the blocking portion. The driving member can abut against the first rod portion and drive the movable member to slide along the first direction. The connecting portion can abut against the inclined surface and rotate around the first direction. The connecting portion further can drive the blocking portion to disengage from the slot.

The elastic member includes a body portion, a first end, and a second end. The first end and the second end are respectively located at two ends of the body portion. The two ends of the body portion respectively abut against the fixing member and the first rod portion. The first end is fixed to the fixing member, and the second end is fixed to the first rod portion.

The movable member further includes a second rod portion located at a side of the first rod portion away from the driving member, and the body portion is sleeved on the second rod portion.

The driving member includes a rotating portion and a handle. The rotating portion is located at one end of the handle. The rotating portion is in contact with the first rod portion. The rotating portion can rotate with the handle and drive the movable member to move along the first direction.

The base includes a supporting portion and a baffle portion each extending along the first direction. Two sides of the supporting portion protrude from the baffle portion along the second direction. The supporting portion and one of the two sides of the baffle portion define the guide groove.

The fixing member and the supporting portion define an accommodating groove. The second rod portion is movably accommodated in the accommodating groove.

The base further includes a first fixing portion and a second fixing portion. The first fixing portion is fixed to the baffle portion. The second fixing portion is fixed to the baffle portion. The first fixing portion and the second fixing portion are spaced apart from each other along the first direction. The locking device further includes a fixing shaft extending through the first fixing portion and the second fixing portion along the second direction. One end of the handle having the rotating portion is sleeved on the fixing shaft. The rotating portion is located between the first fixing portion and the second fixing portion.

A terminal device includes the locking device and the component. The component defines the slot. The locking device can be detachably engaged with the component.

According to the locking device provided in the embodiment of the present disclosure, when the component needs to be unlocked, the driving member is rotated to allow the component to be ejected from the locking device, and then the component can be pulled out. The process of removing the component is simple, and the locking device can automatically return to the original state under the action of the elastic member. Additionally, the volume of the locking device is small.

### BRIEF DESCRIPTION OF THE DRAWINGS

Implementations of the present technology will now be described, by way of example only, with reference to the attached figures.

FIG. 1 is a diagrammatic view of a terminal device according to an embodiment of the present disclosure.

FIG. 2 is a diagrammatic view of a locking device shown in FIG. 1.

FIG. 3 is an exploded view of the locking device shown in FIG. 1.

FIG. 4 is similar to FIG. 3, but showing the locking device viewed from another angle.

FIG. 5 is a diagrammatic view of a movable member of the locking device shown in FIG. 2 being engaged with a slot of a component.

FIG. 6 is a diagrammatic view of the locking device shown in FIG. 5.

FIG. 7 is a diagrammatic view of the locking device unlocked by rotating a driving member of the locking device in FIG. 5.

FIG. 8 is a diagrammatic view of the locking device shown in FIG. 7.

FIG. 9 is a diagrammatic view of a movable member rotated and disengaged from the slot by rotating the driving member shown in FIG. 7.

FIG. 10 is a diagrammatic view of the locking device shown in FIG. 9.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

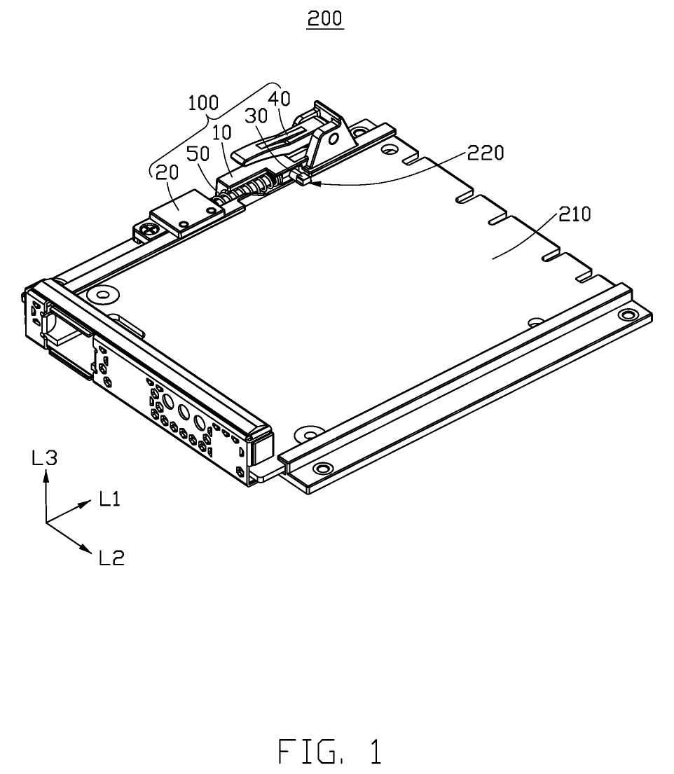

Referring to FIG. 1, FIG. 1 is diagrammatic view of a terminal device 200 according to an embodiment of the present disclosure. The terminal device 200 includes at least one locking device 100 and a component 210. The locking device 100 can be detachably engaged with the component 210 having a slot 220. The terminal device 200 may be a server, and the component 210 may be a circuit board, such as an Open Compute Project (OCP) card.

In some embodiments, the terminal device 200 includes one locking devices 100 disposed at one side of the component 210. In other embodiments, the terminal device 200 may include two locking devices 100 disposed at two sides of the component 210.

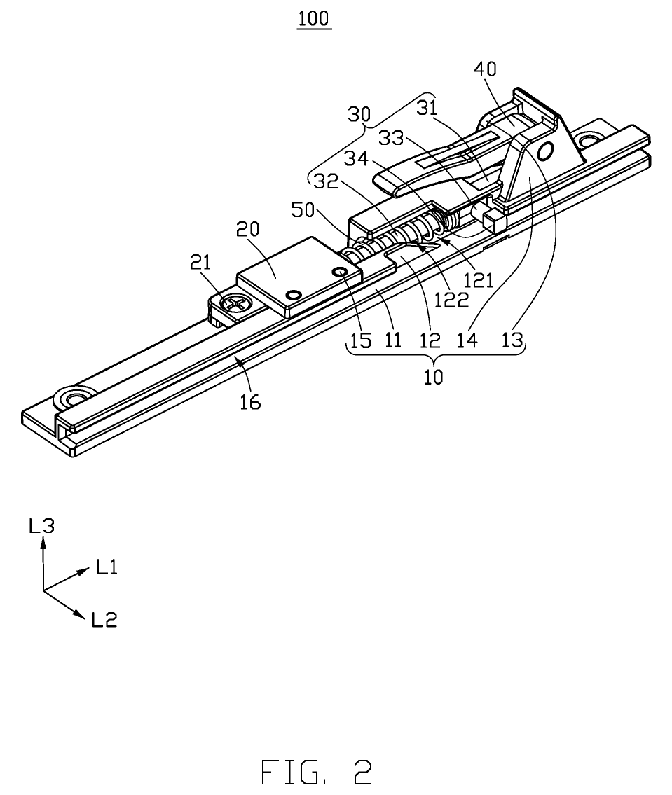

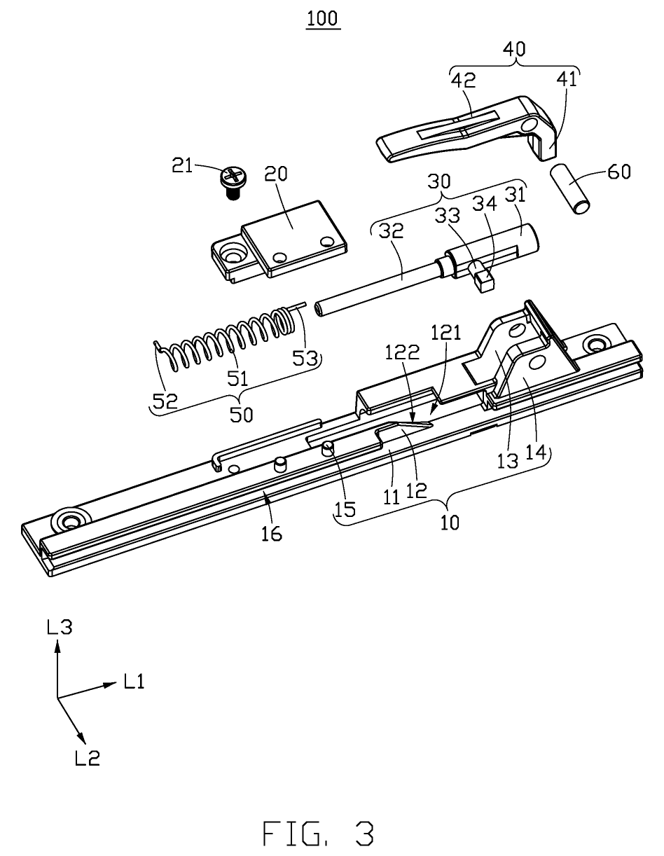

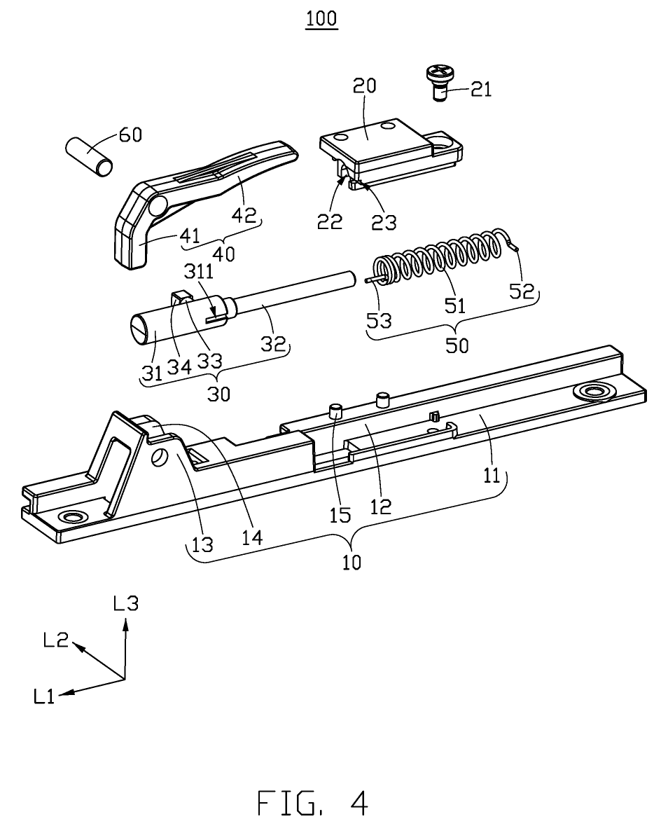

Referring to FIGS. 2, 3, and 4, the locking device 100 may include a base 10, a fixing member 20, a driving member 40, a movable member 30, and an elastic member 50. The fixing member 20 is fixed to the base 10. The driving member 40 is rotatably connected to the base 10. The movable member 30 is movably connected to the base 10. The elastic member 50 is elastically connected to the movable member 30. The elastic member 50 can provide a function of returning the movable member 30 to an original position.

The base 10 may include a supporting portion 11 and a baffle portion 12. Both of the supporting portion 11 and the baffle portion 12 extend along a first direction L1. Two sides of the supporting portion 11 protrude from the baffle portion 12 along a second direction L2. A guide groove 16 is defined between the supporting portion 11 and one side of the baffle portion 12. The guide groove 16 is slidably connect to the component 210, thereby driving the component 210 to slide in the guide groove 16 along the first direction L1.

The baffle portion 12 may include a through hole 121 and an inclined surface 122. The through hole 121 extends through the baffle portion 12 along the second direction L2 and communicates with the guide groove 16. The baffle portion 12 and the supporting portion 11 are disposed along a third direction L3. Two of the first direction L1, the second direction L2, and the third direction L3 intersects with each other and are not coplanar. In the embodiments, two of the first direction L1, the second direction L2, and the third direction L3 are perpendicular to each other.

The inclined surface 122 is a surface for forming the through hole 121. The inclined surface 122 intersects with the first direction L1, the second direction L2, and the third direction L3. The inclined surface 122 can block the movable member 30 to cause the movable member 30 to rotate around the first direction L1, thereby driving the movable member 30 to be disengaged from the slot 220. The inclined surface 122 has a certain curvature, that is, the inclined surface 122 is non-planar. The curvature of the inclined surface 122 matches with the movement trajectory of the movable member 30 relative to the inclined surface 122, which facilitates the rotation of the movable member 30.

The base 10 may further include a first fixing portion 13 and a second fixing portion 14. The first fixing portion 13 is fixed to the baffle portion 12. The second fixing portion 14 is fixed to the baffle portion 12. The first fixing portion 13 and the second fixing portion 14 are spaced apart from each other along the first direction L1.

The locking device 100 may further include a fixing shaft 60. The fixing shaft 60 extends through the first fixing portion 13 and the second fixing portion 14 along the second direction L2. The driving member 40 is sleeved on the fixing shaft 60. The driving member 40 can rotate around the second direction L2, while the fixing shaft 60 functioning as a rotation axis.

The fixing member 20 is located at a side of the baffle portion 12 away from the guide groove 16. The fixing member 20 is spaced apart from the first fixing portion 13 and the second fixing portion 14. The fixing member 20 may be fixed to the base 10 through a pin 21. The base 10 further includes a protrusion 15 fixed to the baffle portion 12. The protrusion 15 extends through the fixing member 20, which facilitates the installation of the fixing member 20.

An accommodating groove 22 is defined between the fixing member 20 and the supporting portion 11. The accommodating groove 22 is recessed along the first direction L1. An opening direction of the accommodating groove 22 faces toward the first fixing portion 13 and the second fixing portion 14.

The driving member 40 may include a rotating portion 41 and a handle 42. The rotating portion 41 is fixed to one end of the handle 42. The end of the handle 42 having the rotating portion 41 is sleeved on the fixing shaft 60. The rotating portion 41 is located between the first fixing portion 13 and the second fixing portion 14. When an external force is applied to the handle 42, the handle 42 rotates and drives the rotating portion 41 to rotate synchronously around the fixing shaft 60.

The movable member 30 can move along the first direction L1 and rotate around the first direction L1. The movable member 30 may include a first rod portion 31, a second rod portion 32, a connecting portion 33, and a blocking portion 34. The first rod portion 31 and the second rod portion 32 are disposed along the first direction L1. Both of the first rod portion 31 and the second rod portion 32 extend along the first direction L1, and are located at a side of the baffle portion 12 away from the guide groove 16. A diameter of the first rod portion 31 is greater than a diameter of the second rod portion 32.

The connecting portion 33 is connected to the first rod portion 31 and the blocking portion 34. The rotating portion 41 abuts against the end of the first rod portion 31 away from the second rod portion 32. When the rotating portion 41 rotates around the fixing shaft 60, the rotating portion 41 drives the first rod portion 31 to move along the first direction L1. The second rod portion 32, the connecting portion 33, and the blocking portion 34 synchronously move along the first direction L1 with the first rod portion 31. After the movable member 30 moves along the first direction L1, a portion of the second rod portion 32 extends into the accommodating groove 22.

The connecting portion 33 is located in the through hole 121. The blocking portion 34 is located at the side of the guide groove 16 and extends into the guide groove 16 relative to the connecting portion 33. When the locking device 100 locks the component 210, the blocking portion 34 is engaged with the slot 220. When the connecting portion 33 moves along the first direction L1 with the first rod portion 31, the connecting portion 33 abuts against the inclined surface 122 and is driven to rotate around the first direction L1 under the action of the inclined surface 122. The blocking portion 34 synchronously rotates around the first direction L1 with the connecting portion 33, while the first rod portion 31 functioning as a rotation axis. The blocking portion 34 moves along the third direction L3 away from the supporting portion 11, thereby disengaging from the slot 220.

The elastic member 50 includes a body portion 51, a first end 52, and a second end 53. The first end 52 and the second end 53 are respectively located at two ends of the body portion 51. The body portion 51 is sleeved on the second rod portion 32. Two ends of the body portion 51 respectively abut against the fixing member 20 and the first rod portion 31. A first groove 23 is defined on the fixing member 20. The first end 52 is located in the first groove 23 and fixed to the fixing member 20. A second groove 311 is defined on the first rod portion 31. The second end 53 is located in the second groove 311 and fixed to the first rod portion 31.

When the movable member 30 moves along the first direction L1 toward the side where the fixing member 20 is located, the first rod portion 31 compresses the elastic member 50, causing the elastic member 50 to be compressive deformed. When the movable member 30 rotates around the first direction L1, the first rod portion 31 drives the second end 53 to rotate relative to the first end 52, causing the elastic member 50 to torsional deform.

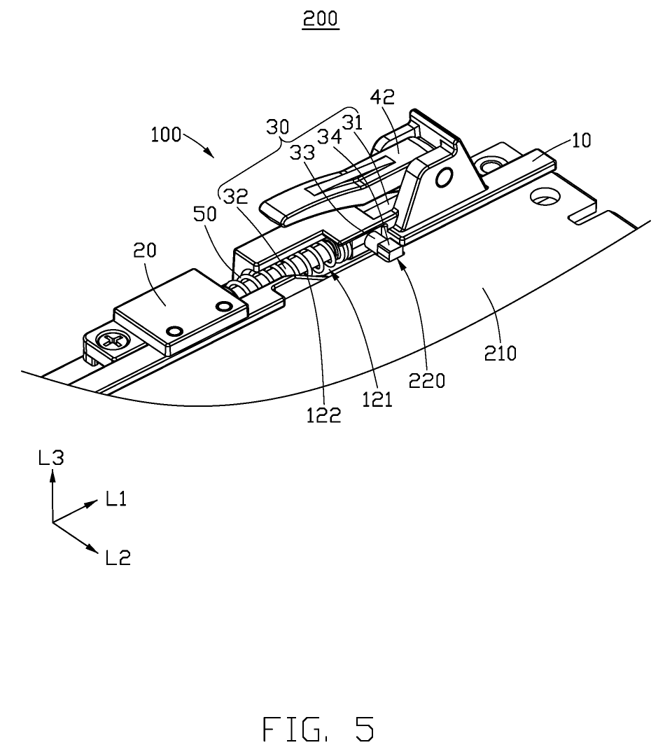

Referring to FIGS. 5 to 10, the relationship between various components of the locking device 100 will be explained through a specific unlocking process.

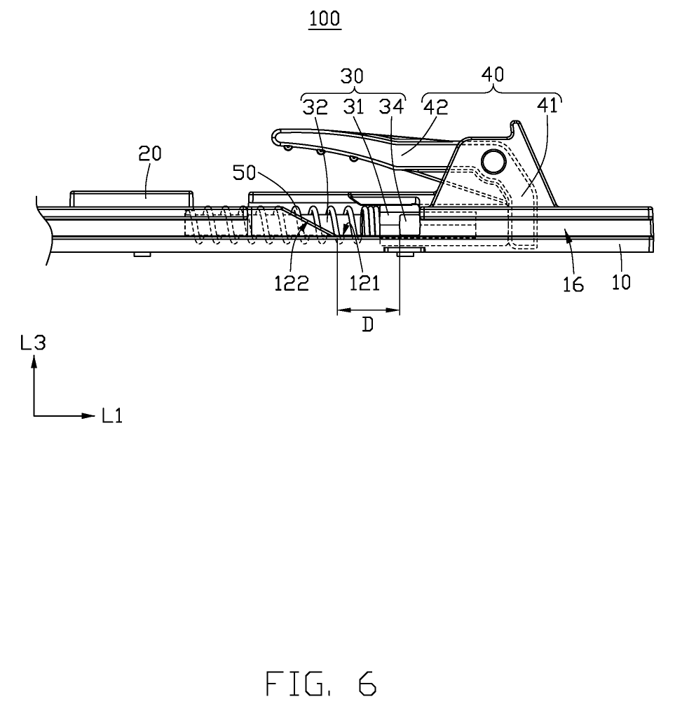

Referring to FIGS. 5 and 6, when the component 210 is placed in the locking device 100, the blocking portion 34 is engaged with the slot 220 of the component 210.

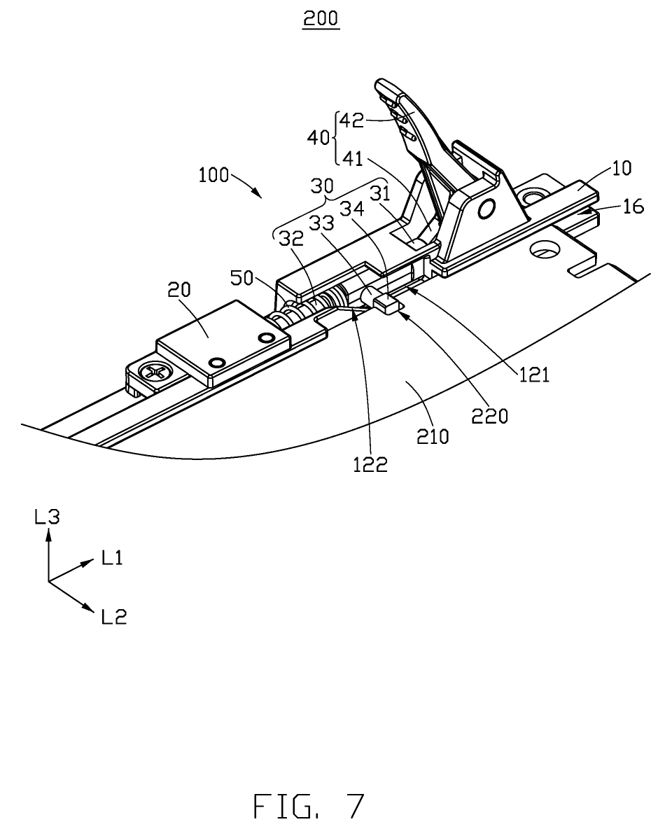

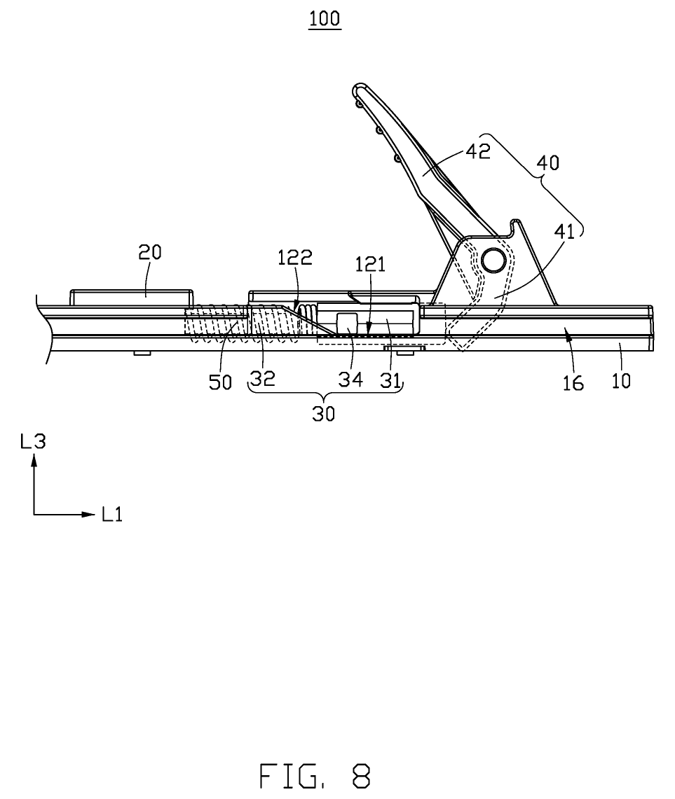

Referring to FIGS. 7 and 8, when the component 210 needs to be unlocked, an external force is applied to the driving member 40 to rotate the handle 42 around the second direction L2, and the rotating portion 41 rotates synchronously with the handle 42. After the rotating portion 41 rotates, the rotating portion 41 drives the movable member 30 to move along the first direction L1 toward the fixing member 20. The movable member 30 drives the component 210 to move along the first direction L1 in the guide groove 16 and compresses the elastic member 50, causing the elastic member 50 to be compressive deformed.

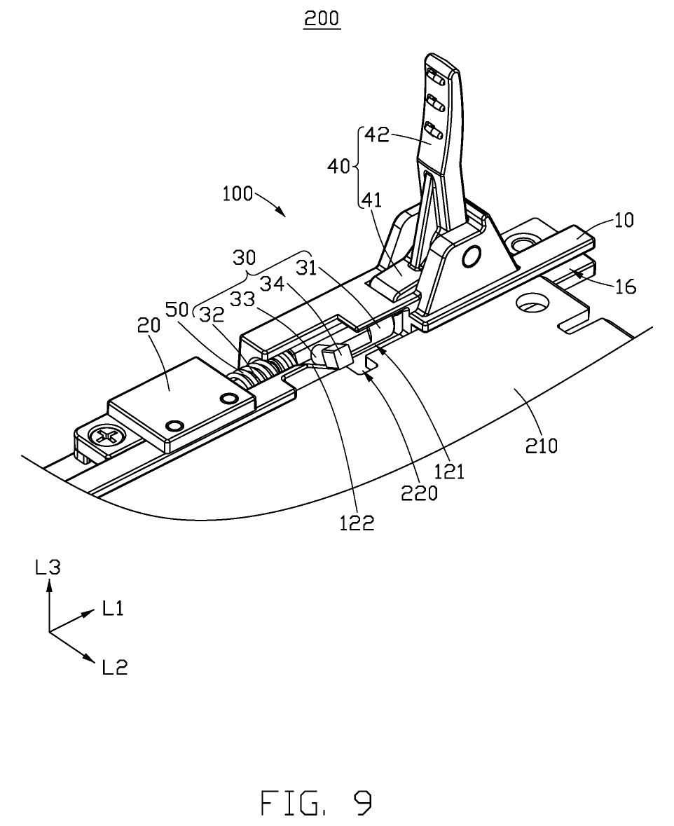

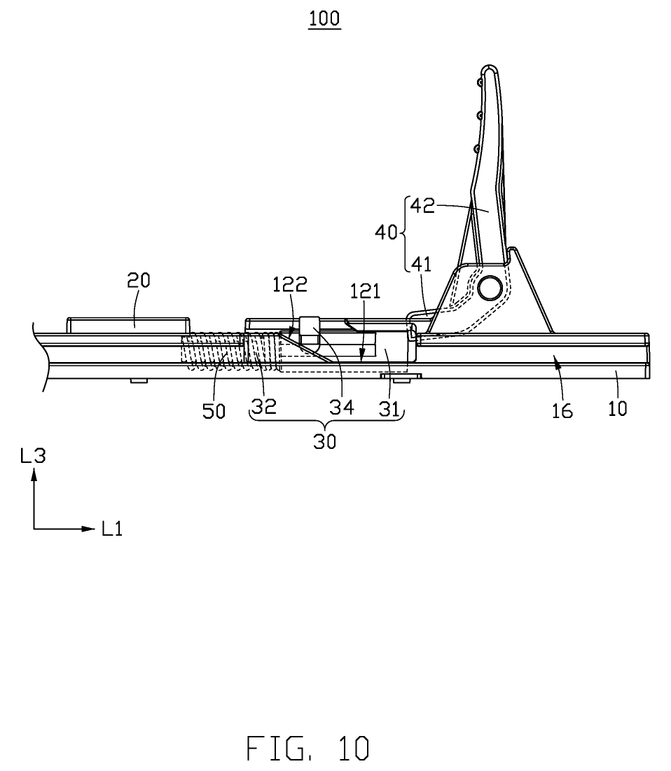

Referring to FIGS. 9 and 10, when the movable member 30 moves along the first direction L1 until the connecting portion 33 is in contact with the inclined surface 122, the inclined surface 122 blocks the connecting portion 33 and allows the connecting portion 33 to slide along the inclined surface 122, the connecting portion 33 rotates around the first direction L1 with the first rod portion 31 as the rotation axis. The blocking portion 34 and the first rod portion 31 rotate synchronously with the connecting portion 33 until the blocking portion 34 is disengaged from the slot 220. The rotation of the movable member 30 drives the elastic member 50 to generate torsional deformation. At this time, the locking device 100 releases the component 210, and the component 210 can be ejected from the guide groove 16. An ejecting dimension of the component 210 is approximately D (referring to FIG. 6).

After the component 210 is ejected from the guide groove 16, the external force applied to the handle 42 is removed, and the movable member 30 and the driving member 40 return to their initial positions under the action of the elastic member 50 (referring to FIG. 6).

When the component 210 is locked to the locking device 100, an external force is applied to the driving member 40 to rotate the handle 42 around the second direction L2. After the driving member 40 rotates, the driving member 40 drives the movable member 30 to move along the first direction L1 until the movable member 30 rotates around the first direction L1. Then, the component 210 slides in the guide groove 16 until the slot 220 aligns with the through hole 121. The external force applied to the handle 42 is removed, and the movable member 30 and the driving member 40 return to their initial positions under the action of the elastic member 50, with the blocking portion 34 being engaged with the slot 220.

According to the locking device 100 provided in the embodiment of the present disclosure, when the component 210 needs to be unlocked, the driving member 40 is rotated to allow the component 210 to be ejected from the locking device 100, and then the component 210 can be pulled out. The process of removing the component 210 is simple, and the locking device 100 can automatically return to the original state under the action of the elastic member 50. Additionally, the volume of the locking device 100 is small.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A locking device configured to lock with a component having a slot, the locking device comprising:
a base defining a guide groove, the guide groove extending along a first direction, the guide groove configured to slidably connect to the component, thereby driving the component to slide in the guide groove along the first direction;
a fixing member fixed to the base;
a movable member configured to move along the first direction and rotate around the first direction, wherein the movable member is engageable with the slot by extending into the guide groove along a second direction;
a driving member rotatably connected to the base, the driving member configured to rotate around the second direction to drive the movable member to move along the first direction; and
an elastic member connected to the movable member and the fixing member, the elastic member compressive deformable along the first direction and torsional deformable around the first direction, wherein when the elastic member is compressive deformed and torsional deformed, the movable member is driven to return to an original position.

2. The locking device of claim 1, wherein the base further comprises an inclined surface intersecting with each of the first direction and the second direction; the inclined surface is configured to block the movable member to cause the movable member to rotate around the first direction, thereby driving the movable member to be disengaged from the slot.

3. The locking device of claim 2, wherein the movable member comprises a first rod portion, a connecting portion, and a blocking portion, the connecting portion is connected to the first rod portion and the blocking portion; the driving member is configured to abut against the first rod portion and drive the movable member to slide along the first direction, the connecting portion is configured to abut against the inclined surface and rotate around the first direction, and the connecting portion is further configured to drive the blocking portion to disengage from the slot.

4. The locking device of claim 3, wherein the elastic member comprises a body portion, a first end, and a second end, the first end and the second end are respectively located at two ends of the body portion, two ends of the body portion respectively abut against the fixing member and the first rod portion, the first end is fixed to the fixing member, and the second end is fixed to the first rod portion.

5. The locking device of claim 4, wherein the movable member further comprises a second rod portion located at a side of the first rod portion away from the driving member, and the body portion is sleeved on the second rod portion.

6. The locking device of claim 4, wherein the driving member comprises a rotating portion and a handle, the rotating portion is located at one end of the handle, the rotating portion is in contact with the first rod portion, and the rotating portion is configured to rotate with the handle and drive the movable member to move along the first direction.

7. The locking device of claim 6, wherein the base comprises a supporting portion and a baffle portion each extending along the first direction, two sides of the supporting portion protrude from the baffle portion along the second direction, and the supporting portion and one of the two sides of the baffle portion define the guide groove.

8. The locking device of claim 7, wherein the fixing member and the supporting portion define an accommodating groove, and the second rod portion is movably accommodated in the accommodating groove.

9. The locking device of claim 7, wherein the base further comprises a first fixing portion and a second fixing portion, the first fixing portion is fixed to the baffle portion, the second fixing portion is fixed to the baffle portion, the first fixing portion and the second fixing portion are spaced apart from each other along the first direction; the locking device further comprises a fixing shaft extending through the first fixing portion and the second fixing portion along the second direction, one end of the handle having the rotating portion is sleeved on the fixing shaft, and the rotating portion is located between the first fixing portion and the second fixing portion.

10. A terminal device comprising:
a component having a slot; and
a locking device configured to lock with the component, the locking device comprising:
a base defining a guide groove, the guide groove extending along a first direction, the guide groove configured to slidably connect to the component, thereby driving the component to slide in the guide groove along the first direction;
a fixing member fixed to the base;
a movable member configured to move along the first direction and rotate around the first direction, wherein the movable member is engageable with the slot by extending into the guide groove along a second direction;
a driving member rotatably connected to the base, the driving member configured to rotate around the second direction to drive the movable member to move along the first direction; and
an elastic member connected to the movable member and the fixing member, the elastic member compressive deformable along the first direction and torsional deformable around the first direction, wherein when the elastic member is compressive deformed and torsional deformed the movable member is driven to return to an original position.

11. The terminal device of claim 10, wherein the base further comprises an inclined surface intersecting with each of the first direction and the second direction; the inclined surface is configured to block the movable member to cause the movable member to rotate around the first direction, thereby driving the movable member to be disengaged from the slot.

12. The terminal device of claim 11, wherein the movable member comprises a first rod portion, a connecting portion, and a blocking portion, the connecting portion is connected to the first rod portion and the blocking portion; the driving member is configured to abut against the first rod portion and drive the movable member to slide along the first direction, the connecting portion is configured to abut against the inclined surface and rotate around the first direction, and the connecting portion is further configured to drive the blocking portion to disengage from the slot.

13. The terminal device of claim 12, wherein the elastic member comprises a body portion, a first end, and a second end, the first end and the second end are respectively located at two ends of the body portion, two ends of the body portion respectively abut against the fixing member and the first rod portion, the first end is fixed to the fixing member, and the second end is fixed to the first rod portion.

14. The terminal device of claim 13, wherein the movable member further comprises a second rod portion located at a side of the first rod portion away from the driving member, and the body portion is sleeved on the second rod portion.

15. The terminal device of claim 13, wherein the driving member comprises a rotating portion and a handle, the rotating portion is located at one end of the handle, the rotating portion is in contact with the first rod portion, and the rotating portion is configured to rotate with the handle and drive the movable member to move along the first direction.

16. The terminal device of claim 15, wherein the base comprises a supporting portion and a baffle portion each extending along the first direction, two sides of the supporting portion protrude from the baffle portion along the second direction, and the supporting portion and one of the two sides of the baffle portion define the guide groove.

17. The terminal device of claim 16, wherein the fixing member and the supporting portion define an accommodating groove, and the second rod portion is movably accommodated in the accommodating groove.

18. The terminal device of claim 16, wherein the base further comprises a first fixing portion and a second fixing portion, the first fixing portion is fixed to the baffle portion, the second fixing portion is fixed to the baffle portion, the first fixing portion and the second fixing portion are spaced apart from each other along the first direction; the locking device further comprises a fixing shaft extending through the first fixing portion and the second fixing portion along the second direction, one end of the handle having the rotating portion is sleeved on the fixing shaft, and the rotating portion is located between the first fixing portion and the second fixing portion.
